(19) United States
(12) Patent Application Publication
(10) Pub. No.: US 2006/0200980 A1
(43) Pub. Date: Sep. 14, 2006

(54) System for producing flexible circuits

(76) Inventor: Norman P. Gagne, Manchester, NH (US)

Correspondence Address: GROSSMAN, TUCKER, PERREAULT & PFLEGER, PLLC, 55 SOUTH COMMERICAL STREET, MANCHESTER, NH, 03101, US

(21) Appl. No.: 11/075,839

(22) Filed: Mar. 9, 2005

(51) Int. Cl. H05K 3/10

(52) U.S. Cl. 29/846; 29/745; 156/272.2

(57) ABSTRACT

A method of producing a flexible circuit according to an embodiment herein include supplying a substrate layer film and supplying a cover layer film. A conductive ink is printed on at least a portion of the substrate layer film using an ink jet printing technique. The cover layer film is then laminated over the substrate layer film to provide the flexible circuit. Of course, many alternatives, variations, and modifications are possible without departing from this embodiment.

### FIELD

The present disclosure generally relates to flexible circuits and systems for the manufacture thereof.

### BACKGROUND

Flat flexible cable is commonly used for connecting electrical devices. Flat flexible cable may provide a structure including multiple conductive pathways and may be easily and reversibly bent and twisted in a narrow and crowded space. Flat flexible cable is often provided as a laminated structure. As a laminated structure, flat flexible cable may generally include a plurality of parallel conductors laminated between opposed insulating sheets or strips. The insulating sheets or strips are often formed from a polymeric material, such as polyester film, polyamide film, etc. Laminated electrical flat conductors may generally be provided as individual conductors in spool form. The individual conductors may be arranged into a conductor set during the process of lamination using slotted guides. The conductor set may include individual conductive pathways. The individual conductive pathways may be individually insulated from each other, i.e., arranged at a spacing relative to each other and have a rectangular cross section. The tops of the conductive pathways may be electrically insulated, for example by an insulating sheet, which is laminated onto the conductive pathways. Similarly, a bottom insulator may also be laminated onto the bottom of the conductive pathways. The top insulator and bottom insulator may be laminated together in the regions between adjacent conductive pathways and on the edges outside of the conductive pathways.

Similar to flat flexible cable, flexible printed circuits or flexible printed circuit boards, may generally include conductive traces on a flexible substrate. The flexible substrate may be a polymeric film similar to the insulting sheets or strips used for flat flexible cable. The conductive traces of the flexible printed circuits may be formed by providing a copper coating on the flexible substrate. The copper coating may be provided using a deposition process or by adhering a copper foil to the flexible substrate. Portions of the copper coating on the substrate that do not correspond to the desired conductive traces may be removed. An acid or caustic material may be used to etch or eat-away the copper layer in the regions that do not correspond to the desired conductive traces. Lithography techniques may be used to mask off the portions of the copper layer corresponding to the desired conductive traces. The lithographically applied mask may protect the covered regions from being etched.

### BRIEF DESCRIPTION OF THE DRAWINGS

Features and advantages of the claimed invention will be apparent from the following detailed description of embodiments consistent therewith, which description should be considered in conjunction with the accompanying drawings, wherein:

FIG. 1 is a schematic illustration of a cold lamination system for manufacturing flexible circuit consistent with the present disclosure;

FIG. 2 is a schematic illustration of a system for continuous manufacture of flexible circuits consistent with the present disclosure; and

FIG. 3 schematically depicts a system for continuous application of a shield and/or dielectric film for a flexible circuit application consistent with the present disclosure.

Although the following Detailed Description will proceed with reference being made to illustrative embodiments, many alternatives, modifications and variations thereof will be apparent to those skilled in the art. Accordingly, it is intended that the claimed subject matter be viewed broadly.

### DETAILED DESCRIPTION

The present disclosure is generally directed at flexible circuits, the production and/or manufacture of flexible circuits, and systems for producing and/or manufacturing flexible circuits. As used in any embodiment herein, flexible circuits include flexible conductive structures, such as flat flexible cables. Additionally, as used herein, flexible circuits include flexible printed circuits and flexible printed circuit boards.

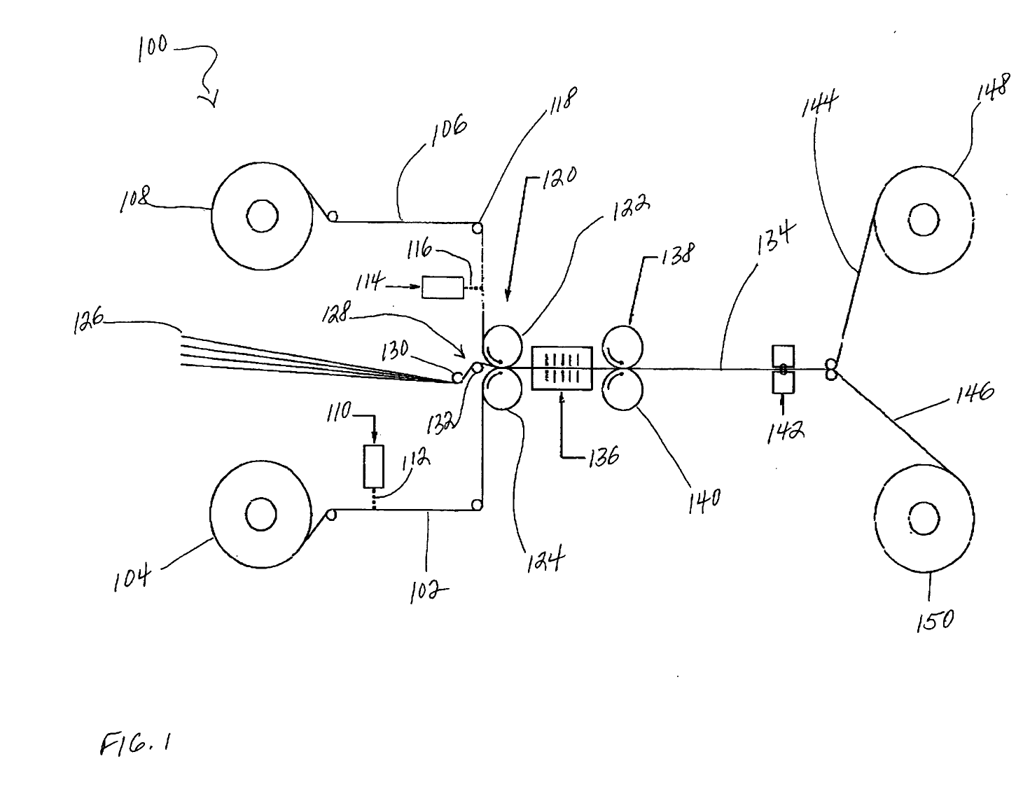

Turning to FIG. 1 a system 100 for producing a flexible circuit is schematically depicted. In general, the system 100 may provide one or more conductive traces and/or electronic features or components laminated between a substrate film and a cover layer film. As shown, the substrate layer film 102 may be supplied from a roll 104. Similarly, the cover layer film 106 may also be supplied from a roll 108. Supplying the substrate layer film 102 and the cover layer film 106 in roll form may allow generally continuous manufacturing of flexible circuits according to the capacity of the substrate layer film roll 104 and the cover layer film roll 108. Additionally, various techniques known in the art may be used to introduce a new substrate layer film roll 104 and/or cover layer film roll 108, i.e., to refresh the supply of substrate layer film 102 and/or cover layer film 106, with minimal or no interruption to the manufacturing process. The substrate layer film 102 and the cover layer film 106 may generally be any electrically insulating film, sheet, or coating. According to one embodiment, the substrate layer film 102 and the cover layer film 106 may be formed from a polymeric sheet or film. Examples of suitable polymeric films or sheets may include polyester film, for example biaxially oriented polyester film available from E.I. du Pont de Nemours and Company under the name Mylar®, polyamide film, as well as numerous other polymeric film and sheet materials.

According to one aspect, a printing unit 110 may be used to deposit conductive and/or dielectric ink 112 patterns on to the substrate layer film 102. According to one embodiment, the printing unit 110 may be an ink jet printing unit. Various other contact and non-contact printing units may also be used herein. The ink 112 deposited to the substrate layer film 102 may form electronic features on the substrate layer film 102. In one embodiment, the electronic features may be conductive traces and/or conductive regions on the substrate layer film 102. In other embodiments, the printing unit 110 may provide various combinations of conductive and/or dielectric ink to provide resistive features, capacitive features, etc. on the substrate layer film 102. Conductive inks may include inks including silver particles, carbon particles, and/or other conductive materials. Additionally, conductive inks may include conductive polymers and/or other conductive components. Conductive inks are commercially available, for example, from Dow Corning Corporation, Cabot Corporation, etc.

Various electronic features may be provided including regions and/or layers having various different electric and/or physical characteristics. For example, electronic features may include regions having different conductivity. The regions having different electrical and or physical characteristics may be arranged in a single layer on the substrate layer film and/or may be provided having an at least partially layered arrangement. An embodiment of an at least partially layered arrangement may include at least one printed region that may be at least partially overlying another printed region and/or at least partially overlying another feature provided on the substrate layer film 102. The various regions having different characteristics may be printed on to the substrate layer film using a single printing unit having a plurality of print heads and/or capable of selectively printing different inks. Alternatively, and/or additionally, a plurality of printing units may be employed to sequentially print conductive and/or dielectric ink on to the substrate layer film and/or to over print previously printed regions of the substrate layer film.

Consistent with the present disclosure, a printing unit may allow a conductive and/or dielectric ink to be applied to specific and/or controlled areas and/or in specific and/or controlled patterns on the substrate layer film or underlying features or patterns. Printing in specific and/or controlled areas and/or in specific and/or controlled patterns may include positioning the printing unit relative to the substrate layer film and/or other features thereon. According to one embodiment, the substrate layer film may include reference marks and/or features. The reference marks and/or features may be detected by suitable systems, such as optical detection systems, magnetic detection systems, etc., depending upon the nature of the reference marks and/or features. The reference marks and/or features may provide linear registration, i.e., along the length of the flexible circuit, and/or may provide transverse registration, i.e., across the width of the flexible circuit.

The system 100 according to the illustrated embodiment may employ a cold lamination method for producing a flexible circuit. Cold lamination may be achieved using an adhesive that may be activated and/or cured by chemical reaction and/or irradiation or exposure to light, such as ultraviolet light (UV), etc. In the illustrated embodiment, a sprayer unit 114 may be provided for spray applying a liquid UV curable adhesive 116 to the cover layer film 106. In alternative embodiments, the UV curable adhesive may be applied using a coating roller, a screed, etc. In still further embodiments, the UV curable adhesive may be pre-applied to the cover layer film and/or may be provided as a separate film layer adhesive. The cold lamination adhesive has been disclosed above as being a UV curable adhesive. Various other non-heat curing/activated adhesives will be appreciated by those having skill in the art.

The present disclosure additionally contemplates the use of heated lamination techniques for the production of the flexible circuits. Embodiments including heated lamination techniques may employ a heat activated adhesive and/or an adhesive that may at least partially fuse to adhere layers of the laminate. The heat activated and/or at least partially fusible adhesive may be provided as a coating applied to the substrate layer film and/or to the cover layer film. The coating may be applied to the substrate layer film and/or to the cover layer film prior to and/or during the formation of the flexible circuit. In other embodiments the heat activated and/or at least partially fusible adhesive may be provided as a film layer that may be introduced at least partially in between the substrate layer film and the cover layer film. In still further embodiments, one or more of the substrate layer film and the cover layer film may be a heat activated and/or at least partially fusible adhesive layer.

One or more idler and/or driven rolls, e.g. roller 118, may be employed to guide and/or position the substrate layer film 102 and/or the cover layer film 106 during application of the ink 112 and/or of the adhesive 116. Following application of the ink 112 and the adhesive 116, the substrate layer film 102, including any printed patterns thereon, and the cover layer film 106, including the spray-coated UV curable adhesive 116, may be laminated to one another. The substrate layer film 102 and the cover layer film 106 may be passed through a consolidating unit 120. The consolidating unit 120 may include a pair of counter-rotating rolls 122, 124. In one embodiment, the rolls 122, 124 may be formed from a compliant material and/or may be formed having a compliant outer surface. For example, the rolls 122, 124 may be rubber rolls or rubber coated rolls. In one embodiment, the counter-rotating rolls 122, 124 may be driven and may draw the substrate layer film 102 and the cover layer film 106 through the consolidating unit 120. The rolls 122, 124 may be spaced press the substrate layer film 102 and the cover layer film 106 together. The pressure provided by the rolls 122, 124 may aid removing air bubbles from between the layers and may create continuous or near continuous contact between the substrate layer film 102 including the printed patterns and the cover layer film 106 including the adhesive 116. Additionally, the rolls 122, 124 may squeeze out any excess adhesive 116 from between the layers.

As shown, one or more conductive wires 126 may be introduced in between the substrate layer film 102 and the cover layer film 106 as the films 102, 106 are drawn through the consolidating unit 120. The conductive wires 126 may, in this general manner, be laminated in between the substrate layer film 102 and the cover layer film 106. The conductive wires 126 may be supplied from a roll (not shown), as with the substrate layer film roll 104 and the cover layer film roll 108, allowing generally continuous manufacturing. The conductors 126 may pass through a guide unit 128. The guide unit 128 may position the conductive wires 126 in between the substrate layer film 102 and the cover layer film 106. As shown in FIG. 1, according to one embodiment, the guide unit 128 may include on or more rolls 130, 132 configured to orient the individual conductive wires 126. For example, one or more of the rolls 130, 132 may include grooves configured to receive a conductive wire 126. In such an embodiment, the conductive wires 126 may be spaced apart generally based on the spacing of the grooves in the rolls. According to an alternative embodiment, the guide unit 128 may be capable of positioning at least one of the conductive wires 126 relative to the substrate layer film 102, the cover layer film 106 and/or one or more pattern printed on the substrate layer film 102. Positioning of the conductive wire 126 may be achieved according to a predetermined program. Alternatively and/or additionally the guide unit 128 may include one or more sensing features, such as an optical imager, to position the conductive wire 126 relative to the substrate layer film 102, the cover layer film 106 and/or one or more pattern printed on the substrate layer film 102.

After passing through the consolidating unit 120, the web 134, including the substrate layer film 102, the cover layer film 106, the adhesive 116, any ink patterns printed on the substrate layer film 102, and the conductive wires 126 may pass through a curing unit 136. In an embodiment in which the adhesive 116 is a UV curing adhesive, the curing unit 136 may include a UV light source, such as one or more UV lamps. In one embodiment, the substrate layer film 102 and/or the cover layer film 106 may be transparent or translucent to UV light, thereby facilitating exposure of the UV curable adhesive 116 to the UV light. As mentioned previously, adhesives other than UV curable adhesives may be employed for laminating the layers together. In such embodiments, the curing unit may be configured according to the mode of curing or setting of the adhesive.

A pair of feed rolls 138, 140 may be provided downstream of the curing unit 136. The feed rolls 138, 140 may pull the web 134 through the curing unit 136. Consistent with one embodiment herein, the feed rolls 138, 140 may be driven rolls and may control the feed rate of the web 134, and the rolls 122, 124 of the consolidating unit 120 may be idler rolls. In such an embodiment the rolls 122, 124 may squeeze the substrate layer film 102 and the cover layer film 106 together with the adhesive 116, conductive wires, and ink patterns therebetween. The layers 102, 106 may be pulled through the rolls 122, 124 by the feed rolls 138, 140. Consistent with alternative embodiments, the rolls 122, 124 may also be driven rolls. The layers 102, 106 may be fed between the rolls 122, 124 by the rotational force applied by the rolls 122, 124.

The system 100 may additionally include a slitting unit 142. The slitting unit 142 may include one or more blades, or other cutting implements configured to cut the web 134. The slitting unit 142 may trim the web 134 into finished flexible circuits 144 and scrap 146. For example, regions along the margin of the web 134 may be trimmed to produce a flexible circuit having a width. Alternatively and/or additionally, a strip and/or region may be trimmed from an interior portion of the web 134, thereby providing more than one finished flexible circuit 144. In an embodiment providing a continuous flexible circuit, e.g., in an embodiment in which the flexible circuit is a flat flexible cable, etc., the finished flexible circuit 144 may be collected on a roll 148. Similarly, in an embodiment in which the scrap 146 is produced in a generally continuous strip, e.g., as may be produced by trimming a margin of the web 134, the scrap 146 may also be collected on a roll 150. According to other embodiments, the slitting unit may cut the web into various lengths and or shapes. In some embodiments in which the web is cut for length, the finished flexible circuits and/or any scrap produced may not be readily susceptible to collection on a roll. In such embodiments, various other collection schemes may be employed.

Consistent with the system shown in FIG. 1, flexible circuits, including flat flexible cables and flexible printed circuits, may be provided as a laminated construction including a substrate layer and a cover layer. The laminated construction may include printed electronic features, such as conductive regions or conductive traces. Additionally, and/or alternatively, electronic features may be produced in the laminated construction using, at least in part, printed conductive regions and/or dielectric regions. According to one embodiment, the printed electronic features may be produced by depositing conductive and/or dielectric ink using an ink jet printer and/or other printing device. The laminated structure may also include conductive wires disposed between the substrate layer and the cover layer. The structure may be laminated together using an adhesive that is not a heat activated or heat setting adhesive. For example, the structure may be laminated together using a UV curable adhesive. The UV curable adhesive may be applied, e.g., by spraying, between the substrate layer and the cover layer. The UV adhesive may then be cured, e.g. by exposing the structure to one or more UV lamps. The laminated structure may be trimmed to produce a continuous flexible circuit and/or to produce several individual flexible circuits.

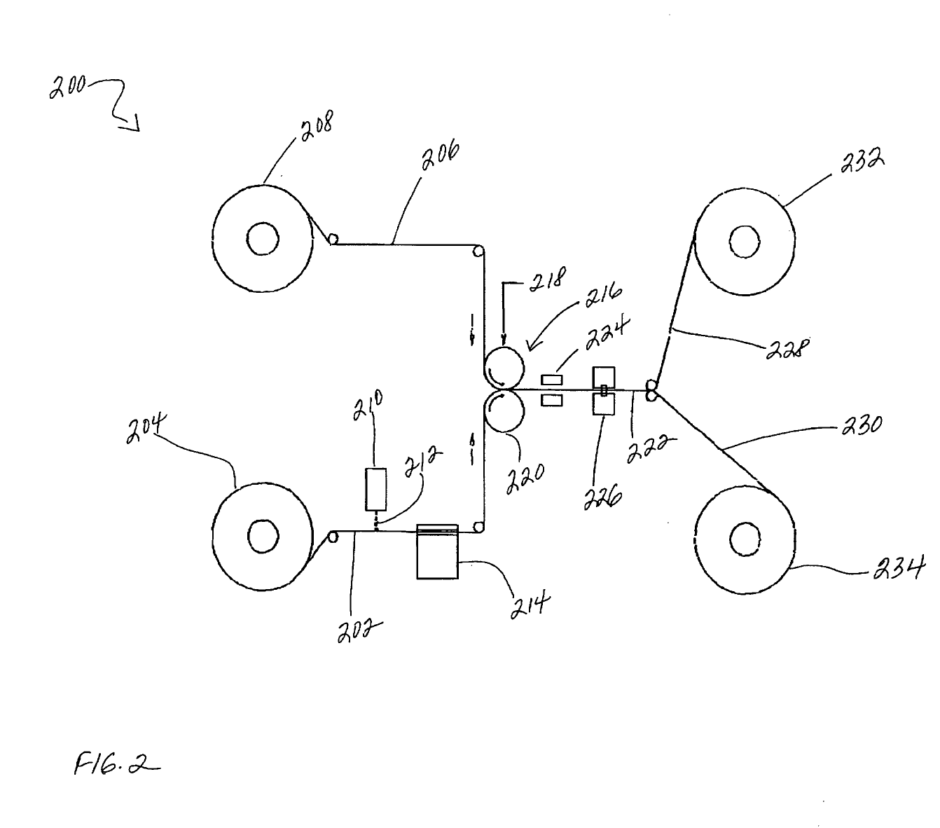

Turning to FIG. 2, another system 200 for producing flexible circuit is schematically depicted. Similar to the previously described embodiment, the disclosed flexible circuit may include a laminated structure. The laminated structure may include a substrate layer film 202, which may be provided from a roll 204, and a cover layer film 206, which may be provided from another roll 208. The system 200 may include a printing unit 210 for applying an ink 212 to the substrate layer film 202. The printing unit 210 may include an ink jet printing unit and/or other suitable contact and/or non-contact printing unit configured to deposit ink on to the substrate layer film 202. The ink 212 may include conductive ink and/or dielectric ink. The ink 212 may be applied in various patterns on the substrate layer film 202. According to one embodiment, the ink 212 may be a conductive ink. The conductive ink 212 may be applied to provide conductive traces along the substrate layer film 202. In one embodiment, the conductive traces of ink using printed by the printing unit 210 may extend in a generally parallel arrangement along the length of the substrate layer film 202. In further embodiments, the printing unit 210 may additionally, or alternatively, be employed to form other electronic features on the substrate layer film using one or more of a conductive ink and/or a dielectric ink. Electronic features formed including ink applied by the printing unit may include, for example, resistive features, capacitive features, etc.

According to various embodiments, the printing unit 210 may include one, or a plurality of, print heads and/or features for depositing ink. Furthermore, a system consistent with the present disclosure may include one or more individual printing units 210. Accordingly, it may be possible to simultaneously and/or sequentially print different inks onto the substrate layer film 202 and/or onto previously printed ink pattern on the substrate layer film. Additionally, and/or alternatively, more than one print head and/or printing unit may allow ink patterns to be printed at more than one region of the substrate layer film at the same time.

As shown, the system 200 may include an ink setting unit 214. The ink setting unit 214 may decrease the setting time of the ink 212 applied to the substrate layer film by the printing unit 210. As used herein, setting of the ink means fixing the ink to decrease the susceptibility of the ink to smudging or displacement resulting from contact with ink. Consistent with the present disclosure, various inks may be employed herein in which the setting of the ink may involve drying, volatilizing solvents, chemical reaction, etc. In an embodiment in which setting of the ink involves drying and/or volatilizing solvents, the setting unit may heat the ink 212 and/or substrate layer film 202 to increase the rate of drying and/or volatilization of solvents. According to such an embodiment, the setting unit 214 may include an infrared heater, a resistive heater, heat lamps, etc. A heat setting unit 214 may additionally include the use of convective airflows. A heating setting unit 214 may also be employed for curing a heat activated or heat set ink, in which a setting chemical reaction is initiated by elevated temperature.

As mentioned above, according to various alternative embodiments the ink 212 may set through a chemical reaction of one or more components of the ink 212. In a particular embodiment, the ink 212 may include a UV curable component. The setting unit 214 may, accordingly, include a UV light source such as one or more UV flood lamps. The ink 212 may, therefore, be set by being exposed to UV light as it passes through the setting unit 214. Setting of a UV curable ink may be further facilitated by providing the substrate layer film as a UV translucent or UV transparent material, thereby allowing exposure of the ink 212 to UV light from both to top and the bottom. Inks having various other setting mechanisms may also suitably be employed herein. The setting unit 214, if any, may be configured corresponding to the setting mechanism of the ink 212.

The substrate layer film 202, having the printed ink patterns thereon, may be introduced into a heated nip roll assembly 216 including counter-rotating, heated rolls 218, 220. The cover layer film 206 may also be introduced to the heated nip roll assembly 216, with the cover layer film 206 positioned to at least partially overlie the printed patterns and the substrate layer film 202. The heated nip roll assembly 216 may press the substrate layer film 202 and the cover layer film 206 together, and may heat the layers 202, 206 to adhere and laminate the layers 202, 206 together. Adhering and laminating the cover layer film 206 and the substrate layer film 202 may include at least partially fusing and/or tacking at least one contacting surface of cover layer film 206 and/or of the substrate layer film 202. A heat activated and/or at least partially fusible adhesive, such as a thermoset polyester adhesive, may be included between the cover layer film 206 and the substrate layer film 202 to assist adhesion and lamination of the cover layer film 206 to the substrate layer film 202 and/or the printed patterns on the substrate layer film 202. The heat activated and/or at least partially fusible adhesive may be provided as a coating or layer on one or both of the cover layer film 206 and the substrate layer film 202. The heat activated and/or at least partially fusible adhesive may additionally, or alternatively, be provided as a separate layer disposed between the substrate layer film 202 and the cover layer film 206.

After passing through the heated nip roll assembly 216, the laminated web 222 may pass through a cooling unit 224. The cooling unit 224 may reduce the temperature of the web 222 and/or reduce the temperature of one or both of the substrate layer film 202 and the cover layer film 206. Reducing the temperature of the laminated web 222 and/or of one or more of the constituent layers thereof may reduce the occurrence of delamination of the web 222. The cooling unit 224 may utilize convective cooling e.g. by providing a fan configured to create a flow of air across the web 222. Other embodiments may employ conductive cooling of the web. Conductive cooling configurations may include passing the web 222 through and/or adjacent to cooled rolls and/or over a cooled surface. Various other arrangements for cooling the laminated web 222 emerging from the heated nip roll assembly 216 may also suitably be employed consistent with the present disclosure.

In a similar manner to the previously described embodiment, the system 200 may include a slitting unit 226. The slitting unit 226 may include one or more blades or cutting features. The blades or cutting features may trim the web 222 to separate finished circuits 228 from scrap 230, for example along the marginal edges of the web 222. The finished flexible circuits 228 may be collected on a first roll 232, and the scrap material 230 trimmed from the web 222 may be collected on a second roll 234. According to other embodiments, the finished flexible circuits and/or the scrap may not be collected on a roll form. For example, slitting unit may cut the finished flexible circuits into lengths that are not readily susceptible to being collected on a roll. Various alternative collection systems may be employed in connection with embodiments in which the finished flexible circuits and/or the scrap are not collected in roll form. In addition to, or as an alternative to, trimming scrap material from the web to provide a finished flexible circuit, the slitting unit may also cut the laminated web into a plurality of individual flexible circuits.

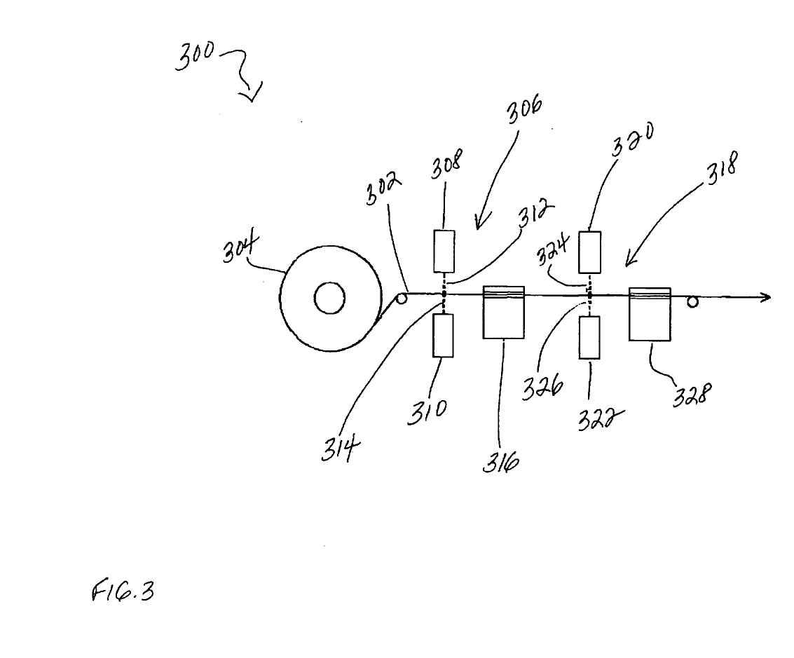

Turning next to FIG. 3, a system 300 is shown for the continuous application of a shield and/or dielectric film for a flexible circuit. As illustrated, a flexible circuit 302 may be supplied from a roll of flexible circuit 304. A first coating unit 306 may apply a shielding to at least a portion of the flexible circuit 302. The shielding may include a conductive layer that may provide EMF and/or RF shielding to at least a portion of the flexible circuit 302. According to an embodiment herein, the first coating unit 306 may include a first and a second printing unit 308, 310. Consistent with the present disclosure, the printing units 308, 310, may include any suitable contact and/or non-contact printing systems, such as ink jet printing units. Each of the printing units 308, 310 may include one or more print heads or features for depositing ink (not shown) for applying a conductive ink, or coating, 312, 314 to at least a portion of each respective side of the flexible circuit 302. According to one embodiment, each printing unit 308, 310 may apply a continuous coating over the respective sides of the flexible circuit. In another embodiment, one and/or both of the printing units 308, 310 may apply conductive ink 312, 314 in a pattern on a portion of the respective side of the flexible circuit 302. Various other coating systems, in addition to ink jet printing units, may also suitably be employed. For example, the conductive material may be applied by spray coating, roller transfer coating, etc.

The use of printing units may allow conductive ink to be easily and/or accurately applied to a defined and/or desired region of flexible circuit. Accordingly, in some embodiments conductive ink may be applied to provide EMF and/or RF shielding to only a defined and/or desired region of the flexible circuit. Application of the conductive ink to a defined and/or desired region may be carried out using control software. One or more of the printing units may include sensors, such as an optical scanner, photoelectric sensor, etc., configured to provide linear and/or transverse registration with the flexible circuit. The sensors may enable the printing unit to print to a desired region on the flexible circuit. Various other known systems may also be used for aligning and/or positioning and printed pattern on the flexible circuit.

The system 300 may include a setting unit 316. The setting unit-316 may be configured to set the ink 312, 314 applied to the flexible circuit 302 and/or to decrease the setting time of the ink 312, 314. Various inks that may suitably be employed in the system 300 may have different setting mechanisms, as discussed previously. Accordingly, the setting unit 316 may include one or more heating units, UV lamps, etc.

A second coating unit 318 may be provided for applying a dielectric material over the previously-applied conductive shielding. Consistent with the illustrated embodiment, the second coating unit 318 may include a third and a fourth printing unit 320, 322. Similar to the first and second printing units 308, 310, the third and fourth printing units 320, 322 may each include at least one print head (not shown) configured to apply a dielectric ink, or coating, 324, 326 to respective sides of the flexible circuit 302. The dielectric ink 324, 326 may at least partially cover and insulate the previously-applied conductive ink 312, 314. Consistent with one embodiment, the dielectric ink 324, 326 may be applied leaving at least a portion of the previously-applied conductive ink 312, 314 exposed. The exposed portions may provide access to allow the conductive ink to be electrically coupled to an electrical feature. For example, the exposed portion of conductive ink 312, 314 may be coupled to a ground, thereby improving the shielding characteristics. According to alternative embodiments, a dielectric coating may be applied over the conductive layer using various other coating techniques, such as spray coating, roller transfer coating, etc.

A second setting unit 328 may be employed to set and/or increase the rate of setting of the dielectric ink 324, 326. The second setting unit 328 may be generally analogous to the first setting unit 316, described above. It should be noted that the setting mechanism of the dielectric ink 324, 326 may be the same as, or may differ from, the setting mechanism of the conductive ink 312, 314. For example, the conductive ink 312, 314 may set under UV exposure while the dielectric ink 324, 326 may set when heated. Accordingly, the configuration of the second setting unit 328 may be selected based on the setting mechanism of the dielectric ink 324, 326. While not shown in FIG. 3, after the dielectric ink 324, 326 has set, the flexible circuit 302 may be collected, for example on a collection roll. In other embodiments, the flexible circuit 302 may undergo subsequent processing, such as trimming, cutting into individual units and/or cutting for length, etc.

The various embodiments set forth herein are provided to illustrate the features and advantages of the claimed subject matter and are not intended to be limiting. Additionally, the various aspects and features of the described embodiments are susceptible to combination with one another. Such combinations should be considered to be within the scope of the present disclosure. Other modifications, variations, and alternatives are also possible. Accordingly, the claims are intended to cover all such equivalents.

What is claimed is:

1. A system for producing a flexible circuit comprising:
a supply of a substrate layer film;
a supply of a cover layer film; and
a printer configured to deposit at least one conductive region on said substrate layer film.

2. A system according to claim 1, wherein said printer comprises an ink jet printer.

3. A system according to claim 1 further comprising a consolidation unit configured to press said substrate layer film and said cover layer film together.

4. A system according to claim 3, wherein said consolidation unit comprises heated rolls.

5. A system according to claim 1, further comprising a sprayer unit for applying an adhesive to at least a portion of said substrate layer film.

6. A system according to claim 5, further comprising a curing unit for setting said adhesive applied to at least a portion of said substrate layer film.

7. A system according to claim 1, further comprising a supply of conductive wires and a guide configured to introduce said conductive wires in between said substrate layer film and said cover layer film.

8. A method of producing a flexible circuit comprising:
supplying a substrate layer film;
supplying a cover layer film;
depositing at least one ink on the substrate layer film forming at least a portion of an electronic feature; and
laminating said cover layer film over said substrate layer film and said ink.

9. A method according to claim 8, wherein said at least one ink comprises a conductive ink.

10. A method according to claim 8, wherein said electronic feature comprises a conductive trace.

11. A method according to claim 8, wherein depositing at least one ink comprises ink jet printing.

12. A method according to claim 8, wherein laminating said cover layer film over said substrate layer film and said ink comprises providing an adhesive between at least a portion of said cover layer film and said substrate layer film.

13. A method according to claim 12, wherein providing an adhesive between at least a portion of said cover layer film and said substrate layer film comprises spaying an adhesive onto at least a portion of said cover layer film.

14. A method according to claim 11, wherein said adhesive comprises an ultraviolet curable adhesive, and said method further comprises exposing said adhesive to an ultraviolet light.

15. A method according to claim 8, wherein laminating said cover layer film over said substrate layer film comprises heating at least one of said cover layer film and said substrate layer film, and pressing said cover layer film and said substrate layer film together.

16. A method according to claim 15, wherein laminating said cover layer film over said substrate layer film comprises passing said substrate layer film and said cover layer film between heated nip rolls.

17. A method according to claim 8, further comprising introducing at least one conductive wire between said substrate layer film and said cover layer film.

18. A method of shielding a flexible circuit comprising:
providing a flexible circuit;
depositing a conductive ink on at least a portion of a first surface of said flexible circuit; and
setting said conductive ink.

19. A method according to claim 18, wherein depositing a conductive ink comprises ink jet printing said conductive ink.

20. A method according to claim 18, further comprising applying a dielectric coating over at least a portion of said conductive ink.

21. A method according to claim 19, wherein applying a dielectric coating comprises ink jet printing a dielectric ink over at least a portion of said conductive ink.

22. A method according to claim 18, further comprising depositing a conductive ink on at least a portion of a second surface of said flexible circuit and setting said conductive ink.

23. A method according to claim 22, wherein depositing a conductive in on at least a portion of said second surface comprises ink jet printing said conductive ink.

24. A method according to claim 22, further comprising applying a dielectric coating over at least a portion of said conductive ink on said second surface of said flexible surface.

25. A method according to claim 24, wherein applying said dielectric coating comprises ink jet printing a dielectric ink.

26. A method according to claim 18, wherein said conductive ink comprises silver.
